(19) United States
(12) Patent Application Publication
(10) Pub. No.: US 2007/0138003 A1
(43) Pub. Date: Jun. 21, 2007

(54) Lamination and conversion process and apparatus

(75) Inventor: Peter W. Quinn, Danbury, CT (US)

Correspondence Address: MICHAUD-DUFFY GROUP LLP, 306 INDUSTRIAL PARK ROAD, SUITE 206, MIDDLETOWN, CT, 06457, US

(73) Assignee: Annaqin LLC, Danbury, CT (US)

(21) Appl. No.: 11/644,320

(22) Filed: Dec. 21, 2006

Related U.S. Application Data
(60) Provisional application No. 60/753,001, filed on Dec. 21, 2005.

(51) Int. Cl. C23C 14/32; C23C 14/00

(52) U.S. Cl. 204/192.38; 204/298.41

(57) ABSTRACT

A coating of a target material is applied onto a substrate by placing the substrate in a chamber and energizing cathodes in the chamber to produce a plasma. Each cathode comprises a target material and is positioned in the same side of the chamber relative to the substrate. The plasma circulates in the chamber. An acid-resistant metal film can be made from an acid-soluble metal by applying the metal onto an acid-resistant substrate as described herein. A cathodic vapor deposition apparatus includes a chamber having a wall, including a wall comprising an access door. There are cathodes on the wall, a pump operatively connected to the chamber, and a fixture in the chamber. The fixture is electrically isolated from the chamber and the cathodes are all on the same side of the fixture. An article of manufacture may contain a polymeric substrate having a film of metal target material deposited thereon by the method described herein, or a metal substrate having a primer thereon, and, on the primer, a film of metal target material.

### CROSS-REFERENCE TO RELATED APPLICATION

This application claims the benefit of U.S. provisional application No. 60/753,001 filed Dec. 21, 2005, the contents of which are incorporated herein by reference in their entirety.

### BACKGROUND

Cathodic Arc Vacuum deposition is a partial pressure, low pressure process for depositing a film of target metal on a substrate. The process is conventionally carried out in a vacuum chamber in which a plate comprised of metallic deposition material is disposed to act as a cathode. An electric arc is generated from an anode to the cathode to generate an emission of vapor comprising the target material by loss of ions and macros (micro-droplets of target material). The vaporized material can be deposited on the surfaces of a substrate that are positioned along a line-of-sight from the cathode. The substrate is negatively biased relative to the chamber anode to facilitate adhesion of the target material. For deposition onto surfaces not on a line-of-sight to a cathode, the substrate must be rotated or multiple cathodes must be placed around the chamber. To achieve a smooth, bright surface, macros must be filtered from the plasma, but doing so greatly reduces deposition rates.

Prior art procedures for using cathodic arc vacuum deposition to apply a metal film onto a polymeric substrate require that the substrate first be etched and then pre-coated with an adhesion-enhancing material before the metal film is applied.

Based on the foregoing, it is the general object of this invention to provide a coating method that improves upon, or overcomes the problems and drawbacks of prior art coating methods.

### SUMMARY OF THE INVENTION

The present invention resides in one aspect in a method for applying a coating of a target material onto a substrate positioned within a chamber. The method includes placing the substrate in the chamber and energizing a plurality of cathodes in the chamber to produce a plasma in the chamber. Each cathode comprises a target material and is positioned in the same side of the chamber relative to the substrate. The method further comprises circulating the plasma in the chamber to deposit target material on the substrate.

The present invention resides in another aspect in a method of producing an acid-resistant metal film from an acid-soluble metal. This method comprises applying the acid-soluble metal as a film onto a substrate as described herein, wherein the substrate is comprised of an acid-resistant material.

In still another aspect, an apparatus for the cathodic vapor deposition of a target material on a substrate comprises a chamber having at least one side wall, a bottom, and a ceiling. A wall is also provided that includes an access door. There is a plurality of cathodes positioned on the wall, and a pump is operatively connected to the chamber. A fixture is also provided in the chamber and is electrically isolated from the chamber. The cathodes are all positioned on the same side of the chamber relative to the fixture.

In another aspect, this invention relates to an article of manufacture that comprises a polymeric substrate having a film of metal target material deposited thereon by thereon by the method described herein.

Alternatively, an article of manufacture may comprise a metal substrate having a primer thereon, and, on the primer, a film of metal target material deposited thereon by the method described herein.

### BRIEF DESCRIPTION OF THE DRAWINGS

FIG. 1 is a schematic perspective view of one embodiment of an apparatus for physical vapor deposition as described herein;

FIG. 2 is a schematic cross-sectional view of a polymeric substrate coated according to one process described herein;

FIG. 3 is a schematic cross-sectional view of a another polymeric substrate coated according to another process described herein; and

FIG. 4 is a schematic cross-sectional view of a metal substrate coated according a process described herein.

### DETAILED DESCRIPTION OF THE INVENTION

This invention provides an apparatus and method for plasma coating of a target material from two cathodes onto surfaces of a substrate that are not necessarily disposed in a line-of-sight to a cathode, a process referred to herein as immersion plasma coating. The immersion plasma coating process is carried out in a vacuum chamber and occurs in a scattered coating zone in the chamber. The cathodes, each comprising a plate of metal target material, are both disposed on the same side of the chamber relative to the substrate. For example, in relation to a substrate placed in a rectangular chamber, the cathodes may both be on the same side wall of the chamber. Substrates may be placed randomly in the scattered coating zone. There is no need to electrically bias the substrate relative to the cathodes. Optionally, a substrate may be placed on a fixture in the chamber; in such case, the cathodes are both on the same side of the fixture.

When the substrate is in the desired position, the cathodes are energized. The cathodes emit ions of the target material that intermix with gas in the chamber (for example, an inert gas such as Argon) to form a plasma. A diffusion pump that communicates with the chamber circulates the plasma in the scattered coating zone of the chamber so that the plasma reaches line-of-sight and non-line-of-sight surfaces of the substrate relative to the cathodes without the need to rotate the substrate in the chamber. For example, the coating may be deposited around and edge of the substrate or in a hole defined by the substrate. Particles of the target material in the plasma settle on the substrate, forming a film thereon. The cathodes are energized for a time sufficient to yield a metallic film of a desired thickness. The cathodes and pump are water-cooled by closed-loop water recirculation. Optionally, the substrate may remain at ambient room temperature throughout the process.

High film adhesion and density and increased surface coverage may thus be attained. The process produces few, if any, macros, and can therefore provide a bright, smooth film without the need to filter the plasma vapor. Deposition can be achieved without the use of volatile organic compounds (VOCs). Accordingly, the process and apparatus avoid the risks of environmental pollution associated with VOCs and the need for preventative and/or remedial measures pertaining thereto.

In some embodiments where metal target material is deposited on a polymeric substrate, a composite material is formed on the substrate surface.

In one embodiment, a substrate is placed in a vacuum chamber having at least one pair of symmetrically equal cathodic arc cathodes each comprising a plate of target material, on a wall of the chamber, one vertically above the other at the vertical centerline of a chamber wall. Optionally, a fixture that can position the substrate in the scattered coating zone in the vacuum chamber is placed in the chamber, and the substrate is placed on the fixture so that it is disposed in the scattered coating zone. The fixture is electrically isolated from the cathodes and from the chamber, i.e., from the chamber walls, bottom and ceiling.

The fixture comprises three shield panels, including a central shield that faces the wall on which the cathodes are mounted, a top shield that faces downward to the chamber bottom and a base shield that faces the top shield. The fixture may travel into and out from the chamber on a removable platform.

The apparatus can accommodate high volume production, short cycle times, low maintenance and little or no operator interface. In a preferred embodiment, the apparatus has automated electronic controls for energizing the cathodes, operating the pump, etc.

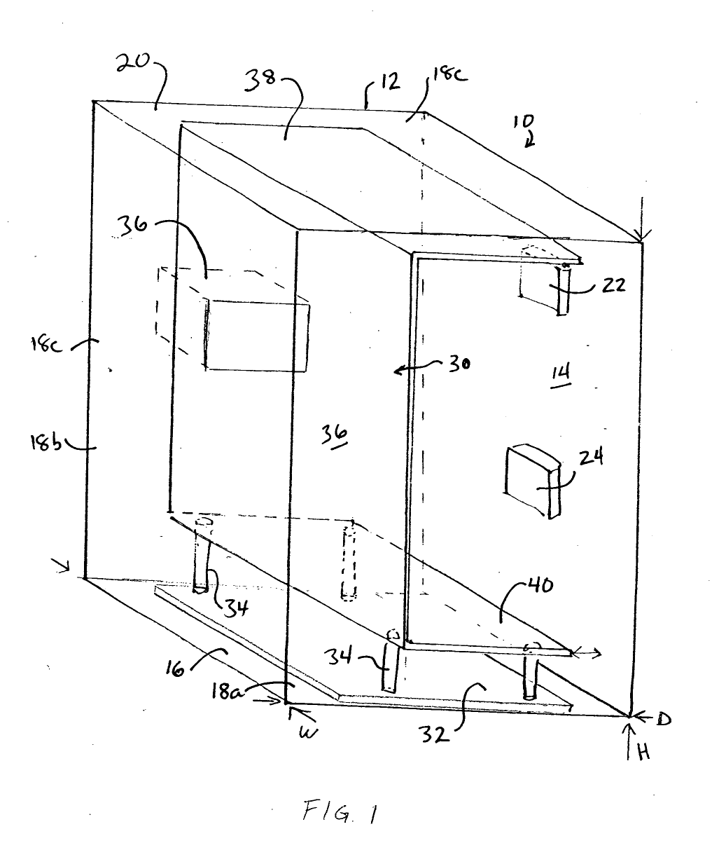

One apparatus suitable for the immersion plasma coating process is shown schematically in FIG. 1 and is generally designated by the reference numeral 10. Apparatus 10 comprises a chamber 12 having a cathode wall 14 and a bottom 16, as well as side walls 18a, 18b, and 18c (one of which comprises an access door) and a ceiling 20. A first cathode 22 and a second cathode 24 are mounted in, but electrically isolated from, cathode wall 14. First cathode 22 and second cathode 24 comprise plates of target material, optionally, chrome.

Inside chamber 12 there is a fixture 30 supported on an optional platform 32 that is removable from the chamber 12. Fixture 30 is supported on the platform 32 by insulated rods 34. Fixture 30 is electrically isolated from chamber 12. Fixture 30 comprises a vertical, central panel or shield 36 that is parallel to wall 14, a top shield 38 and a base shield 40, both of which are parallel to the bottom 18 of the chamber 12. The fixture 30 may be formed from stainless steel. A pump 36 communicates with the interior of chamber 12 via wall 18c. A substrate may be placed on the fixture 30, specifically, on bottom shield 40, within the scattered coating zone of the apparatus.

In a particular embodiment, a vacuum chamber 12 may have a width W of about 101.6 centimeters (cm)(40 inches (in.)), a depth D of about 76.2 cm (30 in.) and a height H of about 152.4 cm (60 in.). In such a chamber, the cathodes may be about 15 cm (6 in.) squares vertically mounted about 56 cm (22 in.) apart from each other and on center with the fixture, and about 48 cm (19 in.) from the bottom of the chamber. The fixture central shield 36 is about 74 cm deep×127 cm high (29×50 in.), the top shield 38 and the base shield 40 are both about 51 cm wide×74 cm deep (20×29 in.). The fixture 30 rest on rods 34 that are about 20.3 cm (8 in.) long. The fixture is placed about 12.7 cm (5 in.) from the cathodes, i.e., the nearest portion of fixture 30 is about 12.7 cm (5 in.) from wall 14. The apparatus provides a scattered coating zone therein that measures about 38 cm×61 cm×122 cm (15×24×48 in.). A substrate to be coated is placed on the fixture, preferably not less than about 23 cm (9 in.) from the faces of the cathodes.

In another embodiment, a chamber is about 100 cm wide×160 cm high×200 cm deep (about 40×64×80 in.) and comprises three pairs of square-faced cathodes, each of which are about 20 cm (about 8 in.) on a side. The cathodes are on a wall of the chamber measuring about 160 cm×200 cm (64×80 in.), arranged in three vertical pairs that are about 40 cm (16 in.) from each other (edge to edge) both vertically and laterally. A diffusion pump operates from the chamber wall opposite from the cathodes.

In a process for depositing metal target material on the surface of a polymer or resin substrate, the substrate is placed on a fixture and the fixture is situated in the chamber to position the substrate in the scattered coating zone. The pressure in the chamber is lowered to 5×10⁻⁵ torr (T). Argon gas is introduced into the chamber, bringing the pressure to 3 millitorr. The cathodes are powered at 100-250 Amperes and an arc is struck on each cathode, thus releasing vaporized ions from the cathode to form a plasma in the chamber. The gas pressure in the chamber is raised to 10-20 mtorr and the substrate is coated for 30 seconds to several minutes, depending on the coating thickness required.

The process causes the formation of a novel composite surface compound that has properties not specific to either the substrate or the target material metal. For example, the foregoing process has been used to deposit chrome target material on various polymeric substrates, including polyester, ABS and resin substrates. Ordinarily, chrome is not soluble in acetone, it is dissolvable in hydrochloric acid and it has low electrical resistivity. However, when chrome is deposited as described herein on a substrate that has a high electrical resistivity and that is soluble in acetone (such as an ABS plastic substrate), the chrome film becomes soluble in acetone. However, when chrome is deposited as described herein on a polymeric substrate that is not soluble in acetone, the chrome film is also insoluble in acetone. Also, hydrochloric acid does not affect a chrome film applied to a polymeric substrate as described herein. In addition, the electrical resistivity of the substrate is affected (reduced) by the chrome. Finally, polymeric substrates that were pliable before the coating process remained pliable even with a film of metal target material applied as described herein. The applied coating will not separate from the substrate surface unless the substrate material breaks down. These results can be attained with almost any plastic substrates.

The applied film of target material has little or no detrimental effect on impact resistance properties of various polymeric substrate materials such as polycarbonate; blends of polycarbonate (PC) with semi-crystalline polyester (e.g., polyolefin terephthalates such as polybutylene terephthalate (PBT) or polyethylene terephthalate (PET)); and blends of polycarbonate and amorphous polyester; amorphous thermoplastic blends of polycarbonate/acrylonitrile-butadiene-styrene (PC/ABS); and polyphenylene ether compounds and blends thereof (e.g., polyphenylene ether/polystyrene). For some materials such as polyolefin terephthalates, impact properties improved upon application of a chrome film as described herein. However, in one test a substrate comprising an amorphous terpolymer of acrylic-styrene-acrylonitrile (ASA) resin, the chrome film appeared to diminish the impact resistance of the material.

Optionally, this process may be incorporated into a manufacturing process for polymeric products, e.g., an injection molding process, such that parts are removed from the molding equipment and placed directly onto a non-rotating fixture that is then conveyed into an apparatus as described herein, where a metal film is deposited on it.

In some embodiments, the vapor deposition process may be followed by the application of another coating layer that may provide additional protection against abrasion and/or improved surface texture (such as smoothness). In such embodiments, the fixture can be removed from the vacuum chamber and placed in another processing area where the subsequent coating can be applied. For example, the fixture may be removed to a liquid spray area for the application of a protective clear ceramic or acrylic coating. The protective layer on the film of target material may be 2 to 4 μm thick and may be cured, e.g., at about 155-174° C. (about 310-345° F.) for 15-20 minutes, after being applied. In a particular embodiment, a plastic substrate having a 2 μm film of chrome deposited thereon will have an additional ceramic coating about 1 mil thick applied over the chrome.

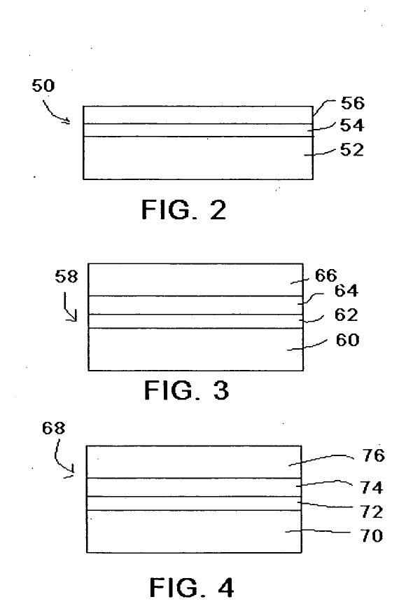

An illustrative embodiment of a product of a process as described herein is shown schematically in FIG. 2. Product 50 comprises a plastic substrate 52 on which a composite surface compound layer 54 has been formed by the cathodic vapor deposition process described herein. The target material of layer 54 comprises chromium and is deposited at a thickness of 0.2 micrometers. Thus, an adherent, flexible film is applied to the plastic substrate without prior etching of the substrate surface. The chromium-coated substrate may then be removed from the deposition apparatus and optionally conveyed to a liquid spray area for application of optional coat of protective clear ceramic or a similar clear or tinted coating is applied in a 56 having a thickness of 1 mil. In other embodiments, layer thickness may be varied from those shown.

The process described herein can be used to apply films onto metal substrates that may comprise aluminum, steel, or zinc. The metal substrate is first prepared by smoothing the surface, e.g., cleaning or polishing out voids that are larger than about 38-50 micrometers (um)(about 1.5 to 2 mils) and are cleaned (preferably without the use of VOCs) to remove grease etc. Steel substrates may be treated with a conversion coating wash. The metal substrates are then treated with a deionized water rinse, and dried, e.g., at about 120-150° C. (about 250-300° F.). To promote adhesion of the plasmatized target material, a primer is applied to the metal substrate. The primer may be organic or nonorganic (e.g., ceramic), and may in liquid or powder form, e.g., epoxy powder. The primer may be applied electrostatically, to a thickness of about 75 to 125 micrometers (about 3-5 mil), and may be cured, e.g., at about 200-230° C. (about 400-450° F.). The primer serves to level and seal the substrate surface. The primed metal substrates are then allowed to cool and may then be treated by physical vapor deposition as described herein. The process time for the deposition may be 10 minutes or less. Optionally, a post-target material coating may also then be applied.

A sample metal substrate treated in this way is shown schematically in FIG. 3. Product 58 comprises a metal substrate 60 on which a 3-mil thick layer of primer 62 is applied as just described. After cooling to below 150°, a layer 64 comprising target material is deposited on primer 62 the process described herein. The target material of layer 64 comprises chromium and is deposited at a thickness of about 0.25 micrometers. The plasma coated substrate is then removed from the deposition apparatus and an optional clear coat 66 of acrylic or a like material having a thickness of 2-3 mil is applied over layer 64 and is then cured at 310-345° F. for 15-20 minutes.

In an alternative embodiment, a protective layer of ceramic may be deposited on target material layer 64 instead of coat 66.

A product comprising a metal substrate but made in an alternative procedure is shown schematically in FIG. 4. In this embodiment, a layer of ceramic is applied to the primer before the target material is deposited. Product 68 comprises a metal substrate 70 on which a 3-mil thick layer of primer 72 is applied as described above. After the primer layer cools, a coat 74 of liquid ceramic is applied electrostatically, at room temperature, over primer 72 after the primer cools, to a thickness of 1 mil. Coat 74 dries in less than two minutes. A layer 76 of target material is then applied onto the coat 74 by the cathodic vapor deposition process described herein. The target material of layer 76 comprises chromium and is deposited at a thickness of about 0.5 micrometers. The ceramic coat 74 enables the target material comprising layer 76 to be thicker and harder than it would be if the target material were deposited on the primer 72.

Unless otherwise specified, all ranges disclosed herein are inclusive and combinable at the end points and all intermediate points therein. The conjunction term “and/or” indicates that the terms so conjoined are meant individually, or in combination, or both. The terms “first,” “second,” and the like, herein do not denote any order, quantity, or importance, but rather are used to distinguish one element from another. The terms “a” and “an” herein do not denote a limitation of quantity, but rather denote the presence of at least one of the referenced item. Likewise, the terms ‘top’ and ‘bottom,’ “upper” or “above” and “lower” or “below” refer to relative positions.

Although the invention has been described with reference to particular embodiments thereof, it will be understood by one of ordinary skill in the art, upon a reading and understanding of the foregoing disclosure, that numerous variations and alterations to the disclosed embodiments will fall within the spirit and scope of this invention and of the appended claims.

What is claimed is:

1. A method for applying a coating of a target material onto a substrate in a chamber, comprising:
placing the substrate in the chamber;
energizing a plurality of cathodes in the chamber, each cathode comprising a target material and being on the same side of the chamber relative to the substrate, to produce a plasma in the chamber;
circulating the plasma in the chamber to deposit target material on the substrate.

2. The method of claim 1 wherein the chamber is a rectangular chamber comprising four side walls and the cathodes both on the same side wall of the chamber.

3. The method of claim 1, comprising placing the substrate on a fixture in the chamber, wherein the fixture comprises insulative material for contact with the bottom of the chamber.

4. The method of claim 1 wherein the substrate comprises a surface in a line-of-sight from an electrode and a second surface not in a line-of-sight from either electrode, and the method further comprises not rotating the substrate in the scattered coating zone, and wherein the method is effective to deposit target material on the first surface and on the second surface.

5. The method of claim 1 wherein the substrate comprises a polymeric substrate.

6. The method of claim 1 wherein the substrate comprises a polymeric substrate selected from the group consisting of polycarbonate; blends of semi-crystalline polyester and polycarbonate (PC); and blends of polycarbonate and amorphous polyester; amorphous thermoplastic blends of polycarbonate/acrylonitrile-butadiene-styrene (PC/ABS); and polyphenylene ether (PPO) compounds and blends thereof (e.g., polyphenylene ether/polystyrene).

7. The method of claim 1, wherein the substrate comprises metal having a primer layer on which the coating is applied.

8. The method of claim 7, wherein the substrate comprises metal having a primer layer thereon and a layer of ceramic on the primer, wherein the method comprises depositing the target material on the coating of ceramic.

9. The method of claim 7, wherein the method further comprises applying a protective layer comprising ceramic or polymeric material on the coating of target material.

10. The method of claim 1, wherein the method further comprises applying a protective layer comprising ceramic or polymeric material on the coating of target material.

11. The method of claim 1, performed without the use of VOCs.

12. A method of producing an acid-resistant metal film from an acid-soluble metal, comprising applying the acid soluble-metal as a film onto a substrate according to the method of claim 1, wherein the substrate is comprised of an acid-resistant material.

13. An apparatus for the cathodic vapor deposition of a target material on a substrate, comprising:
a chamber having a wall, a bottom, and a ceiling, including a wall comprising an access door;
a plurality of cathodes on the wall,
a pump operatively connected to the chamber; and
a fixture in the chamber, wherein the fixture is electrically isolated from the chamber and the cathodes are all on the same side of the fixture.

14. The apparatus of claim 13, wherein the chamber is rectangular and comprises a cathode wall and three side walls.

15. An article of manufacture, comprising:
a polymeric substrate having a film of metal target material deposited thereon by the method of claim 1.

16. An article of manufacture, comprising:
metal substrate having a primer thereon, and, on the primer, a film of metal target material deposited thereon by the method of claim 1.
